(19) United States
(12) Patent Application Publication
(10) Pub. No.: US 2007/0012429 A1
(43) Pub. Date: Jan. 18, 2007

(54) Heat Transfer Device

(75) Inventor: Wing Ming Siu, Kowloon City (HK)

Correspondence Address: EDELL, SHAPIRO & FINNAN, LLC, 1901 RESEARCH BOULEVARD, SUITE 400, ROCKVILLE, MD, 20850, US

(73) Assignee: CONVERGENCE TECHNOLOGIES, INC., San Po Kong, Kowloon (HK)

(21) Appl. No.: 11/426,416

(22) Filed: Jun. 26, 2006

Related U.S. Application Data
(60) Provisional application No. 60/693,484, filed on Jun. 24, 2005.

(51) Int. Cl. H05K 7/20

(52) U.S. Cl. 165/104.33; 165/80.3; 361/700

(57) ABSTRACT

A heat transfer device includes a vapor chamber that houses a phase change material such as water. The heat transfer device may be selectively formed from a combination of polymeric and non-polymeric materials. In one embodiment, the vapor chamber is formed from a polymer layer surrounding a sealing layer formed from non-polymeric material. The heat transfer device may further include one or more fin members operable to diffuse heat from the vapor chamber to the ambient/outside environment. The fins may be solid structures, or may each define a fin chamber in communication with the vapor chamber. In one embodiment, the fin members are formed from non-polymeric material.

### CROSS-REFERENCE TO RELATED APPLICATION

This application claims priority from U.S. Provisional Patent Application Ser. No. 60/693,484, entitled “Organic-Inorganic Vapor-Augmented Heatsink” and filed 24 Jun. 2005. The disclosure of the above-mentioned provisional application is incorporated herein by reference in its entirety.

### TECHNICAL FIELD

This invention relates to heat transfer devices, and more particularly, to a vapor augmented heat sink device selectively formed from both polymeric and non-polymeric materials.

### BACKGROUND OF THE INVENTION

As electronic components and devices decrease in size while increasing in operational speed, generated heat becomes a major obstacle to improving performance in electronic devices and systems. The development of high performance heat transfer devices becomes a major focus of the industry.

A heat transfer device is often used for removing the heat from a system to the ambient environment. In particular, a heat sink (an environment or object that absorbs heat from another object by means of thermal contact (in either direct or radiant contact)) is commonly used for thermal management of electronic devices or electronic systems. A higher thermal performance heat sink can provide lower total thermal resistance (which represents the performance of a heat transfer/cooling device). The total thermal resistance is dependent upon two variables: conductive resistance within a heat sink and convective resistance between the heat sink and the ambient environment. When a conductive element is involved, conductive resistance exists. Therefore, more conductive materials, such as copper or aluminum, are often employed for making heat sinks. With the demand of the high cooling requirement, solid diffusion can only marginally satisfy the cooling requirement. More efficient mechanisms have been developed and evaluated. A vapor chamber has been one of those commonly considered mechanism.

Vapor chambers (i.e., heat pipe chambers) have been used for enhance heat transfer/cooling ability of heat transfer devices, such as heat sinks, by reducing the conductive resistance. Vapor chambers make use of the heat pipe principle that heat is carried by the evaporated working fluid and is spread by the vapor flow. The vapor eventually condenses over the cool surfaces; as a result, the heat is distributed from the evaporation surface (the interface with the heat source) to the condensation surfaces (the cooling surfaces). That is, inside a heat pipe, “hot” vapor flows in one direction, condenses to the liquid phase, and flows back in the other direction to evaporate again and close the cycle. If the cooling surfaces are positioned higher than the evaporation surface, the spreading of heat can be achieved with almost no temperature difference, since it is a phase change (liquid-vapor-liquid) mechanism that occurs with isothermal condition.

Although the vapor chamber can be utilized to create cooling systems with higher cooling efficiency, its construction can be too expensive for adaptation in commodity markets such as the desktop PC market. For such markets, OEMs are often willing to trade off performance to save cost, as the large volume adds up to a significant cash saving. As such, for such commodity market, a different type of vapor chamber is needed in order to address the performance-per-dollar issue. To accomplish this, a different class of vapor chamber is required. Typically, in order to minimize thermal resistance, vapor chambers are made of metals, but in this way, the cost from the material and the associated process can render it too expensive.

### SUMMARY OF THE INVENTION

A heat transfer device includes a vapor chamber that houses a phase change material such as water. The heat transfer device may be selectively formed from a combination of polymeric and non-polymeric materials. In one embodiment, the vapor chamber is formed from a polymer layer surrounding a sealing layer formed from non-polymeric material. The heat transfer device may further include one or more fin members operable to diffuse heat from the vapor chamber to the ambient/outside environment. The fins may be solid structures, or may each define a fin chamber in communication with the vapor chamber. In one embodiment, the fin members are formed from non-polymeric material. In operation, heat created by an object is transferred to the phase change material such as water. The phase change material evaporates, spreading vapor within the chamber. The vapor eventually condenses over cool surfaces of the chamber, distributing heat from the evaporation surface (the interface with the heat source) to the condensation surfaces (the cooling surfaces). Thus, the vapor flows in one direction, condenses to the liquid phase, and flows back in the other direction to evaporate again and complete the cycle.

### BRIEF DESCRIPTION OF DRAWINGS

FIG. 1 illustrates an exploded view of a folded flat plate vapor chamber in accordance with an embodiment of the invention, showing a body and end caps.

FIG. 2 is a cross sectional view of the body of the vapor chamber of FIG. 1.

FIG. 3 illustrates a perspective view of a vapor chamber according to another embodiment of the invention, showing staggered fin members.

FIG. 4 is cross sectional view of the vapor chamber of FIG. 3.

FIG. 5 is cross sectional view of a vapor chamber according to another embodiment of the invention, showing heat dispersion fins including a groove wick.

FIG. 6 is cross sectional view of a vapor chamber according to another embodiment of the invention, showing fins coupled to the sealing layer.

FIG. 7 illustrates a perspective view of a heat transfer device according to an embodiment of the invention, showing a folded vapor heat sink.

FIG. 8 illustrates a cross sectional view of the heat transfer device of FIG. 7.

FIG. 9 illustrates a cross sectional view of a heat transfer device according to another embodiment of the invention, showing a vapor chamber having a wick structure.

FIG. 10 illustrates a cross sectional view of a heat transfer device according to another embodiment of the invention, showing a vapor chamber including a boiler plate.

FIGS. 11 and 12 illustrate a partial cross sectional views of a vapor chamber, showing techniques for adhering the polymer material layer to the layer made of inorganic material.

Like reference numerals have been used to identify like elements throughout this disclosure.

### DETAILED DESCRIPTION OF THE INVENTION

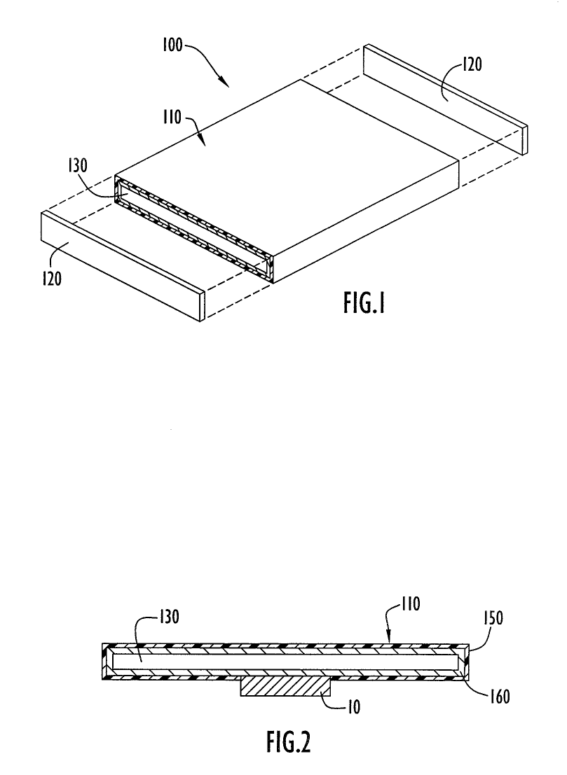

FIG. 1 is a heat transfer device 100 according to an embodiment of the invention. As shown, the heat transfer device 100 may be a heat sink formed from a folded plate chamber including a generally hollow body 110 and two end caps 120. The body 110 defines a vapor chamber 130, i.e., an enclosure under vacuum pressure. The vapor chamber 130 may house at least one type of phase change material. This material can be solid, liquid, or gaseous, and can be a mixture or pure substance. By way of example, the phase change material may be a refrigerant, water, alcohol, ammonia, etc. In operation, the heat transfer device 100 absorbs heat form a heat source 10 (FIG. 2) such as an electronic device. The heat from the heat source 10 causes the liquid phase change material to evaporate, generating vapor that is transported to the interior surface of the device 100. When the vapor leaves the evaporation zone (i.e., the area in the immediate vicinity of the heat source), the vapor condenses, releasing the heat into the chamber walls. The heat, in turn is transmitted to the ambient environment via convection. The condensed liquid travels back toward the evaporation zone (i.e., toward the heat source 10). This evaporation-condensation process can continue, with the heat from the heat source 10 being diffused from the top surface of the device.

The heat transfer device 100 may be selectively formed from a combination of polymeric materials and non-polymeric materials. Generally, forming a heat sink device 100 using polymeric materials is desirable because of the material is inexpensive and is easily processed. However, a vapor chamber formed solely of polymeric material is not structurally sound. In order for a vapor chamber to work correctly, the interior of the chamber must operate under vacuum pressure. Polymers are relatively porous, also tend to outgas at low pressure, and are capable of undergoing sublimination. This, in turn, leads to leaks (both actual and virtual) in the vapor chamber that compromises the required vacuum level. Thus, maintaining a vacuum in a vapor chamber formed solely of polymeric material is difficult. Sealing the vapor chamber is also difficult, since the sealing agent may not have the requisite adhesion, reliability, and outgassing behavior. Non-polymeric materials such as metals avoid the drawbacks associated with polymers, but are expensive and costly to process.

To address these issues, the components of the inventive heat sink device 100 may be singly or collectively formed from a combination of polymeric and non-polymeric materials. FIG. 2 is a cross sectional view of the folded plate chamber illustrated in FIG. 1. In the embodiment shown, the body 1 10 includes a first or polymer layer 150 and a second or sealing layer 160. The polymer layer may comprise a polymeric material. Polymeric material includes polymers (molecules having structural units and repeating units) such as thermoplastics (e.g., polyethylene terephthalate, polystyrene, nylon, etc.), thermosetting polymers, elastomers (e.g, polybutadiene), and coordination polymers. The polymeric material includes both organic and inorganic polymers (e.g., silicone polymers). The material may comprise a single polymer of a mixture of polymers. The polymer layer 150 provides mechanical strength to the heat transfer device 100.

The sealing layer 160 is operable to create a fluid impermeable barrier within the vapor chamber of the heat transfer device 100 (e.g., between the phase change material and the external/ambient environment). The sealing layer 160 may be formed from a non-polymeric material. A non-polymeric material includes any material operable to maintain vacuum conditions, provide a fluid-impermeable barrier, and permit the transfer of energy (thermal energy) therethough. Thus, sealing layer not only prevents fluid from escaping to the ambient environment, but also prevents fluid from entering the chamber 130 (e.g., by gases released by sublimation of the polymer layer). By way of example, the non-polymeric material may include, but is not limited to generally nonporous, thermally conductive materials such as metals (copper, silver, aluminum, iron, etc.), diamond, ceramics, cermets, and mixtures thereof. The thickness of the sealing layer 160 includes any thickness operable to provide the aforementioned fluid barrier properties. By way of specific example, the sealing layer 160 may include a metal foil layer having a thickness of about 1 μm to about 30 μm. The manner of forming the sealing layer 160 is not particularly limited. By way of example, the sealing layer may be formed via painting, electroless plating, vapor deposition, lamination, adhesion, chemical bonding, diffusion bonding, welding, etc.

The manner of forming the heat transfer device is not particularly limited. By way of example, the polymer layer 150 may be formed via extrusion, molding (transfer molding, injection molding, blow molding), etc. The sealing layer 160 may be formed (subsequently or simultaneously) on the polymer layer 150 using any of the aforementioned techniques. As noted above, the polymeric material provides mechanical strength to the structure. In addition, since it is less expensive to process than non-polymeric materials, it reduces the overall cost of producing the heat transfer device). The non-polymeric material protects the integrity of the chamber 130, preventing the polymeric material from interacting with the vacuum condition. The non-polymeric material further serves to minimize conductive resistance within the chamber 130, particularly at high heat-flux regions where the base portion of the chamber contacts the heat source 10.

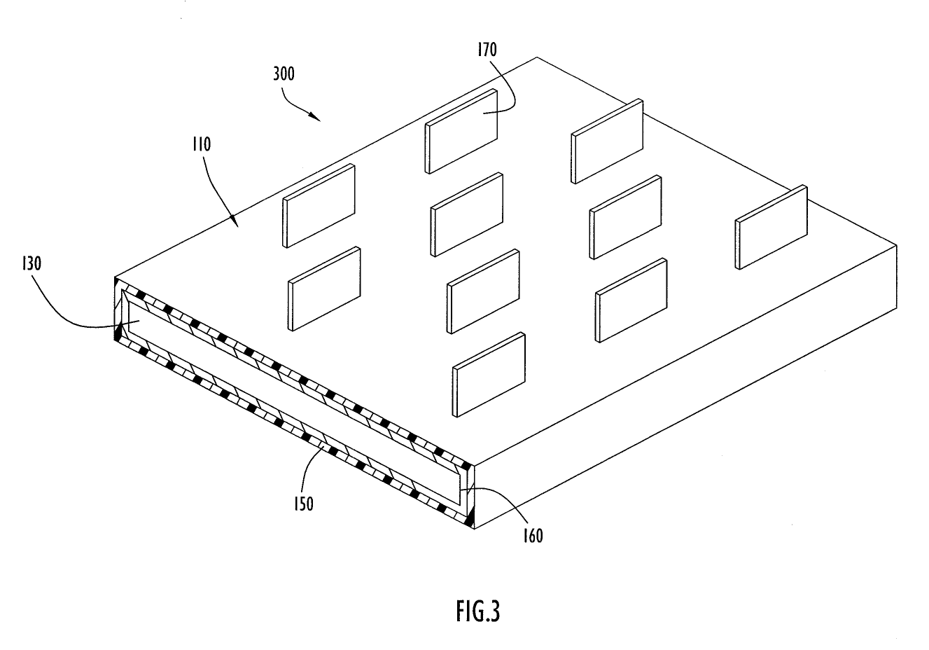

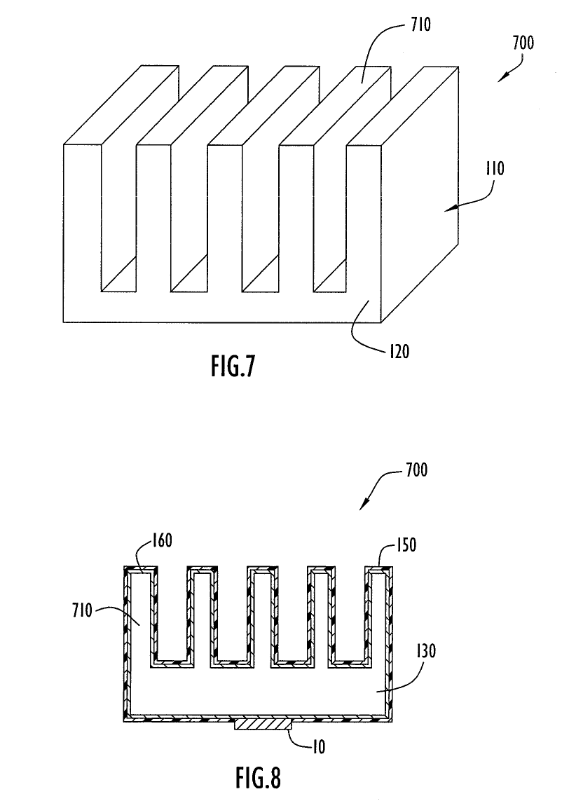

FIG. 3 is a heat transfer device according to another embodiment of the invention. As shown, the heat transfer device 300 includes a structure similar to that described above, including a body 110 with polymer 150 and sealing layers 160, as well as end caps (not shown). In addition, the heat transfer device 300 may further include one or more fin members 170 operable to diffuse heat from the vapor chamber 130. The fin members 170 (also called fins) may include, but are not limited to, chamber fins (wherein the fins are an extension of the vapor chamber 130 (as illustrated in FIG. 8), solid fins, perforated fins, etc. The number, orientation, dimensions, shape, and placement of the fins 170 are not particularly limited. As shown in FIG. 3, the fins 170 may be placed in a staggered formation to maximize airflow around the fins 170. The material forming the fins 170 may include, but is not limited to, non-polymeric materials as described above (e.g., metals). Forming the fins 170 from non-polymeric materials provides reduced conductive resistance (compared to polymeric materials), which provides for more effective heat diffusion.

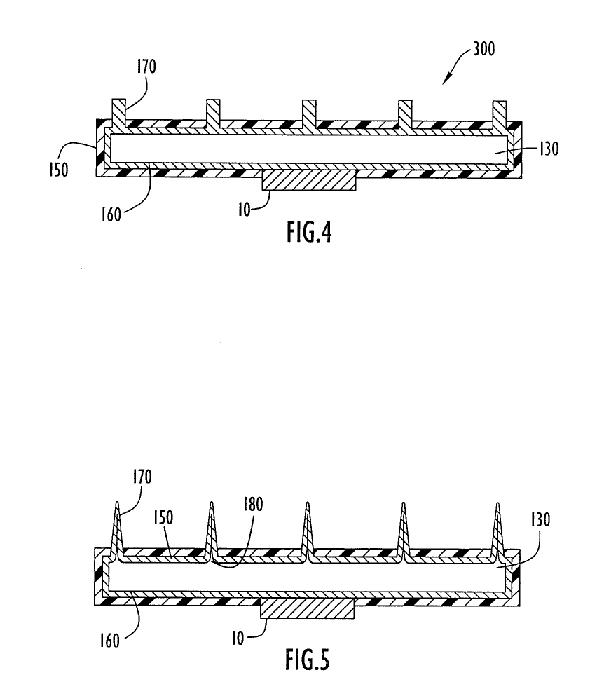

The exterior surface of the fins 170, are typically exposed to the ambient environment, being configured to extend beyond the sealing layer 160 of the heat transfer device 300. The fins 170 may be formed as integral part of the sealing layer 160, or be formed as separate components (described in greater detail below). FIG. 4 is a cross sectional view of the heat transfer device 300 shown in FIG. 3. As illustrated, each fin 170 is formed as a part of the sealing layer 160, protruding through the polymer layer 150 at desired locations (i.e., the sealing layer extends through the polymer layer 150 at sleeted intervals). The structure of the fins 170 is not limited to the embodiments illustrated. By way of further example, and as illustrated in FIG. 5, the heat transfer device 300 may include a series of folded, generally triangular fins 170. The base of each fin 170 (the base of the triangle), includes a groove 180 capable of serving as a wicking structure for the condensate. As the vapor condenses, heat is released, which is diffused by the fins 170 to the ambient environment.

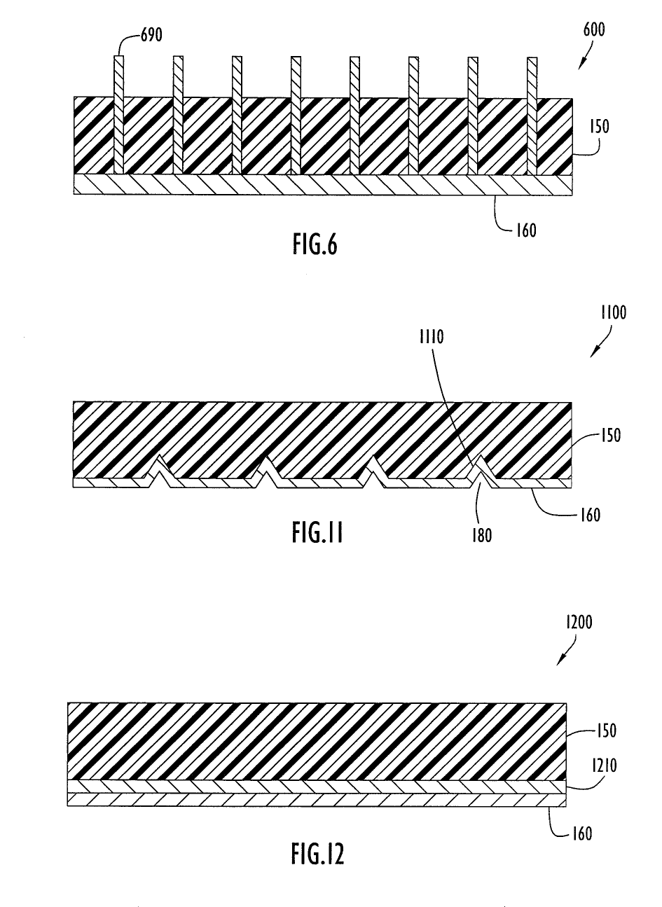

The fins 170 may alternatively be formed as separate components coupled to the sealing layer 160. FIG. 6 is partial cross sectional view of the heat transfer device 600 according to another embodiment of the invention, showing the sealing layer 160, the polymer layer 150, and a series of component fins 690 selectively connected to the sealing layer 160. Specifically, a plurality of fins 690 is disposed along the top surface of the heat transfer device 600. The fins 690 may be formed from non-polymeric material as described above. Each fin 690, moreover, may have a composition that is the same as or different from that of the sealing layer 160. Each fin 690 extends through the polymer layer 150, contacting the sealing layer 160. The fins 690 may be functionally joined to the sealing layer 160 via, for example, sintering, molding, welding, diffusion bonding, chemical bonding, etc.

FIGS. 7 and 8 show a heat transfer device according to another embodiment of the invention. Referring to FIG. 7, the heat transfer device 700 may include a body 120 and end caps 120 that define a vapor chamber 130. In addition, the heat sink device 700 may include one or more chamber fins 710 in fluid communication with the vapor chamber 130. This configuration forms a thermal transfer device 700 having a heat pipe configuration 700, wherein the condensate collects within the fin chambers 710 and is drawn back down towards the heat source 10. In this embodiment the polymer layer 150 may completely surround the sealing layer (as illustrated); alternatively, the polymer layer 150 may be omitted from the areas surrounding the fins 710 (leaving the outer surface of the sealing layer 160 exposed to the ambient environment).

The heat transfer device of the invention may further include one or more wicking structures operable to wick condensed liquid back toward the vapor chamber 130 and, specifically, toward the evaporation zone (the region in the vicinity of heat source 10). FIG. 9 illustrates a cross sectional view of a heat transfer device 900 according to an embodiment of the invention, showing a central wicking structure 910 and two lateral wicking structures 920. The wicking structure 910, 920 may include, but is not limited to, screen structures, groove structures, porous structures, capillary structures, channel structures, etc.

In addition, the chamber may include multi-wick structure with at least one wick type that spatially varies wicking power and/or provides to a three-dimensional condensate flow. By way of specific example, the multi-wick structure may include a plurality of interconnected wick structures, wherein the multi-wick structure has a wicking power factor that decreases with an increasing distance from the evaporation zone such that an increased wicking capability exists as liquid converges toward the evaporation zone. This spatially-varying-wicking capability can be provided by a plurality of different wicking structures having differing amounts or types of material. Further, the multi-wick structure can include wick structure bridges that connect different wick structures and provide additional paths back to the evaporation zone, preferably more direct paths, or “short cuts”, to the evaporation zone.

Thus, the multi-wick structure provides a flow path back to the evaporation zone. As condensate flows toward the evaporation region, the volume of liquid, and hence the flow rate, increases with decreasing distance to the evaporation region, with the local flow rate at the most remote points being small and the flow rate near the evaporation region being greatest. The increasing wicking power of the multi-wick structure matches the increasing flow requirements and can be achieved by using an increasing amount of wicking material (e.g., greater layer thickness) and/or using combinations of wicking materials (e.g., grooves and mesh in combination) that provide an overall reduction in the resistance to flow in the direction of the evaporation region. Additional information regarding the wicking structure is provided in U.S. Published Patent Application No. 2004/0011509 (Siu), the disclosure of which is incorporated herein by reference in its entirety.

The wicking structures may be selectively applied to the interior surface of the vapor chamber 130 (e.g., the sealing layer 160). These wicking structures may be formed from polymeric material and/or non-polymeric material (as described above). By way of specific example, in the embodiment of FIG. 9, the central wicking structure 910 includes a three-dimensional wick structure formed from non-polymeric material. The central structure 910 includes a base 930 functionally disposed on the sealing layer 160 and a wicking bridge 940 extending upward from the base 930 toward the fins 170. In addition, the lateral wicking structures 920 may include a metallic mesh layer 950 functionally disposed on the sealing layer 160, as well as a metal plate layer 960 situated on top of the mesh layer 950. The metal plate 960 applies a downward force to the mesh layer 950 toward the sealing layer 160, keeping the mesh layer in contact with the bottom surface of the vapor chamber 130 (i.e., the sealing layer 160). This, in turn, increases the wicking power of the mesh-chamber-assembly by increasing the surface area the condensate may contact.

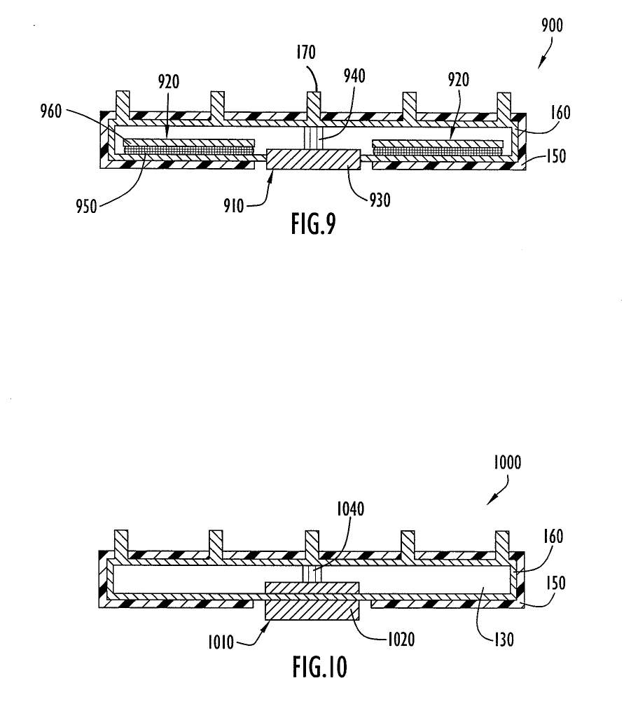

The heat transfer device may further include a boiler plate operable to manage any superheat generated at the evaporation zone. FIG. 10 is a cross sectional view of a heat transfer device 1000 according to another embodiment of the invention. As shown, the boiler plate 1010 may be disposed on the sealing layer 160, proximate the heat source 10. The boiler plate 1010 may be formed from either polymeric material or non-polymeric material (as described above). The boiler plate 1010 may also include a protruding wick structure (also described above). In addition, a wick bridge 1010 may be provided. The wick structure associated with the boiler plate 1010 increases wicking ability and provides an additional wicking path for the condensate flow. This additional condensate flow helps to maximize the amount of liquid capable of reaching the central portion of the evaporation zone. As with the above-mentioned wicking structures, the wicking structure of the boiler plate 1010 may include structures such as screen-type, groove type, porous-type, capillary-type, channel-type, etc.

Improved adhesion of the layer of non-polymeric material (the sealing layer 160) to the layer of polymeric material (the polymer layer 150) may be provided using various techniques. FIG. 11 illustrates a partial cross sectional view of the heat transfer device 11000, showing a close-up view of the polymer layer 150 and the sealing layer 160. As illustrated, the polymer layer 150 includes a series of divots 1110 formed along its surface. These divots 1110 provide additional surface area for the sealing layer 160 to engage, creating a mechanical interlock that improves the adhesion of the sealing layer 160 to the polymer layer 150. When the application of the sealing layer 160 is maintained at a constant thickness, a series of grooves 180 similar to those described above with reference to FIG. 5 is formed, providing a wicking area that is capable of capturing vapor (described above).

Alternatively or additionally, an adhesion promotion layer may be utilized to improve the adhesion of the polymer layer 150 to the sealing layer 160. FIG. 12 illustrates a partial cross sectional view of the heat transfer device 1200, showing a close-up view of the polymer layer 150 and the sealing layer 160. As shown, an adhesion promotion layer 1210 may be disposed between the polymer layer 150 and the sealing layer 160. The adhesion layer 1210 may be formed from a metal oxide such as copper oxide (black oxide). Other materials capable of providing bonding may also be used. In addition the sealing layer, when it comprises a metal, may be subject to a black oxide conversion process, where a caustic solution reacts with the iron in the metal to form an integral protective surface.

To provide additional rigidity to the vapor chamber 130, supports (not illustrated) may be interposed between the walls of the vapor chamber 130. These supports may further be configured to provide wicking functions, and may include structures such as screen-type, groove type, porous-type, capillary-type, channel-type, etc.

The heat transfer device may further include a pump (not illustrated) operable to assist the motion of the fluid within the chamber. The pump may include, but is not limited to, a regular pump, a micro-pump (such as an electro-kinetic pump), etc. The pump may be housed within or without the vapor chamber 130, and may join the condensing region with the evaporation zone. Alternatively, the pump may move fluid through a tube that extends our from the vapor chamber 130 to an external device, providing additional cooling.

While the invention has been described in detail and with reference to specific embodiments thereof, it will be apparent to one skilled in the art that various changes and modifications can be made therein without departing from the spirit and scope thereof. For example, the heat transfer device may comprise any configuration, be of any shape, and have any dimensions suitable for its described purpose. Similarly, the structure of the vapor chamber 130 is not limited, and may include any structure capable of sustaining a vacuum condition. The configuration of the vapor chamber, moreover, may be altered to suit various application requirements. For example, the simplest format is that of a flat heat spreader such that the heat from the heat source is transported from one side to another side of the vapor chamber having functionally attached fins. Another format is that of a rectangular or cylindrical heat sink. The vapor chamber 130 may be further implemented in the form of casing, rack, and/or cabinet. To improve functional contacts between the heat source (e.g. electronic device) and the vapor chamber, a thermal connection can be used. This thermal connection can be a conductive solid element, an ordinary heat pipe, and/or another vapor chamber. By way of further example, the heat transfer device may be in the form of a clip that clips on the printed circuit board (especially for daughter board). The vapor chamber may be formed from one integral component or be formed from a plurality of components joined together. This order of coupling components and/or layers forming the heat transfer device is not limited.

The configuration for the end caps 120 is not particularly limited. The end caps may be integral with the body 110 of the heat transfer device, or may be separate components that couple to the body 110 to form a fluid tight seal. The end caps may be composed of the same material that composes the main body, e.g., including a sealing layer and a polymer layer. Wick structures may be formed on the end caps 120 to provide an additional condensate flow path.

The heat transfer device and its components (e.g., the vapor chamber and/or the fins) may be formed entirely of polymeric material, entirely of non-polymeric material, or may include a mixture of thereof. In addition, portions of the components may be selectively formed from polymeric and/or non-polymeric material. By way of example, in applications requiring higher performance in the vapor chamber 130 and the fins 170, 690 may be formed from non-polymeric material.

Thus, it is intended that the present invention covers the modifications and variations of this invention provided they come within the scope of the appended claims and their equivalents. For example, it is to be understood that terms such as “left”, “right” “top”, “bottom”, “front”, “rear”, “side”, “height”, “length”, “width”, “upper”, “lower”, “interior”, “exterior”, “inner”, “outer” and the like as may be used herein, merely describe points of reference and do not limit the present invention to any particular orientation or configuration.

I claim:

1. A heat transfer device comprising:
a vacuum chamber including;
a first layer comprising polymeric material, and
a second layer comprising non-polymeric material, wherein the second layer is operable to provide a fluid barrier under vacuum conditions; and
a phase change material housed within the vacuum chamber, wherein the heat transfer device is operable to transport heat from a heat source to an ambient environment.

2. The heat transfer device of claim 1 further comprising at least one fin member operable to convect heat from the vacuum chamber to an ambient environment.

3. The heat transfer device of claim 2, wherein the at least one fin member comprises non-polymeric material.

4. The heat transfer device of claim 2, wherein the at least one fin member comprises a plurality of fin members disposed in a staggered formation.

5. The heat transfer device of claim 2, wherein the at least one fin member comprises a section of the sealing layer.

6. The heat transfer device of claim 2, wherein the at least one fin member is a component coupled to the sealing layer.

7. The heat transfer device of claim 1, wherein the polymeric material is selected from the group consisting of organic polymers, inorganic polymers, thermoplastics, thermosetting polymers, and elastomers.

8. The heat transfer device of claim 1, wherein the non-polymeric material is selected from the group consisting of metals, ceramics, cermets, and a mixture thereof.

9. The heat transfer device of claim 1 further comprising a fin chamber in communication with the vacuum chamber.

10. The heat transfer device of claim 1 further comprising a boiler plate disposed proximate the heat source.

11. The heat transfer device of claim 10, wherein the boiler plate is formed from material selected from the group consisting of polymeric material and non-polymeric material.

12. The heat transfer device of claim 1 further comprising a wicking structure to accommodate the in increase flow rate of a condensate as the condensate accumulates and converges toward an evaporation zone within the chamber.

13. The heat transfer device of claim 12, wherein the wicking structure is formed from material selected from the group consisting of polymeric material and non-polymeric material.

14. The heat transfer device of claim 1 further comprising an adhesion promotion layer formed between the first layer and the second layer.

15. The heat transfer device of claim 1, wherein a surface of the first layer comprises cavities operable to increase the adhesion of the second layer to the first layer.
